(19) United States
(12) Patent Application Publication
(10) Pub. No.: US 2003/0216035 A1
(43) Pub. Date: Nov. 20, 2003

(54) Method and apparatus for sputter deposition

(75) Inventors: Suraj Rengarajan, San Jose, CA (US); Michael Miller, Sunnyvale, CA (US); Darryl Angelo, Sunnyvale, CA (US); Nirmalya Maity, San Jose, CA (US); Peijun Ding, San Jose, CA (US)

Correspondence Address: PATENT COUNSEL, APPLIED MATERIALS, INC., Legal Affairs Department, P.O. BOX 450A, Santa Clara, CA, 95052, US

(73) Assignee: Applied Materials, Inc.

(21) Appl. No.: 10/439,021

(22) Filed: May 14, 2003

Related U.S. Application Data
(60) Provisional application No. 60/380,385, filed on May 14, 2002.

(51) Int. Cl. C23C 14/00; C23C 14/32; H01L 21/4763

(52) U.S. Cl. 438/637; 204/192.17

(57) ABSTRACT

A physical vapor deposition chamber is employed to sputter-deposit a layer of material, such as a tantalum or tantalum nitride barrier layer, in a via formed on a semiconductor substrate. After the sputter-deposition step, a second processing step is performed in which material from the barrier layer is back-sputtered from the bottom wall of the via. The second step is performed at a high pedestal bias and with substantial power applied to the sputtering target. The power applied to the sputtering target in the second step may be at a higher level than the power applied to the sputtering target in the first step. Numerous other aspects are provided.

### CROSS REFERENCE TO RELATED APPLICATION

This application claims priority from U.S. Provisional Patent Application Serial No. 60/380,385, filed May 14, 2002, which is hereby incorporated by reference herein in its entirety.

The present application is related to U.S. Provisional Patent Application Serial No. 60/380,386, filed on May 14, 2002 and titled “Method and Apparatus for Sputter Deposition” (AMAT Docket No. 6172), which is hereby incorporated by reference herein in its entirety.

### FIELD OF THE INVENTION

The present invention is concerned with fabrication of semiconductor devices, and is more particularly concerned with sputtering of materials onto semiconductor substrates.

### BACKGROUND OF THE INVENTION

Semiconductor device fabrication typically involves depositing and patterning a number of layers on a substrate such as a silicon wafer. One widely used method of forming material layers on silicon wafers is known as sputtering or sputter deposition (also referred to as physical vapor deposition (PVD)).

A first conventional PVD reactor is schematically illustrated in cross-section in FIG. 1A. The reactor 10 is of a type sometimes referred to as an SIP (self ionizing plasma) chamber. Reference numeral 10 generally indicates the PVD reactor. The reactor 10 includes a sealable chamber 12, and a target 14 installed at the top of the chamber 12. The target 14 is composed of a material, usually a metal, to be sputter deposited on a wafer 16 held on a pedestal 18. A shield 20 installed within the chamber 12 protects walls of the chamber 12 from material sputtered from the target 14 and provides a grounding anode. A variable (DC) power supply 22 is connected to the target 14 for supplying power thereto.

A working gas supply 23, which includes a working gas source 24 and a first mass flow controller 26, supplies a working gas (typically the chemically inactive gas argon) to the chamber 12. If reactive sputtering is to be performed to sputter-deposit a metal nitride layer, such as TaN, a second gas supply 25 may be provided, including a nitrogen gas source 27 and a second mass flow controller 29. The chamber 12 is shown as receiving argon and nitrogen near the top of the chamber 12, but may be reconfigured to receive argon and nitrogen at other locations, such as near the bottom of the chamber 12. A pump 28 is provided to pump out the chamber 12 to a pressure at which sputtering is performed; and an RF power source 32 is connected to the pedestal 18 through a coupling capacitor 34 (e.g., for biasing the wafer 16 during sputtering).

A controller 30 is provided to control operation of the reactor 10. The controller 30 is operatively connected to control the DC power supply 22, the first mass flow controller 26, the second mass flow controller 29, the pump 28, and the RF power supply 32. The controller 30 similarly may be coupled to control the position and/or temperature of the pedestal 18. For example, the controller 30 may control the distance between the pedestal 18 and the target 14, as well as heating and/or cooling of the pedestal 18. To promote efficient sputtering, a magnetron 36 may be rotationally mounted above the target 14 to shape the plasma. The magnetron 36 may be of a type which produces an asymmetric magnetic field which extends deep into the chamber 12 (e.g., toward the pedestal 18), to enhance the ionization density of the plasma, as disclosed in U.S. Pat. No. 6,183,614. U.S. Pat. No. 6,183,614 is incorporated herein by reference in its entirety. Typical ionized metal densities may reach 10¹⁰ to 10¹¹ metal ions/cm³ when such asymmetric magnetic fields are employed. In such systems, ionized metal atoms follow the magnetic field lines which extend into the chamber 12, and thus coat the wafer 16 with greater directionality and efficiency. The magnetron 36 may rotate, for example, at 60-100 rpm. Stationary magnetic rings may be used instead of the rotating magnetron 36.

In operation, argon is admitted into the chamber 12 from the working gas supply 23 and the DC power supply 22 is turned on to ignite the argon into a plasma. Positive argon ions thereby are generated, and the target 14 is biased negatively relative to the grounded shield 20. These positively charged argon ions are attracted to the negatively charged target 14, and may strike the target 14 with sufficient energy to cause target atoms to be sputtered from the target 14. Some of the sputtered atoms strike the wafer 16 and are deposited thereon thereby forming a film of the target material on the wafer 16.

A DC self bias of the wafer 16 results from operation of the RF power supply 32, and enhances efficiency of sputter deposition (e.g., by attracting ionized target atoms which strike the wafer 16 with more directionality). As stated, the use of asymmetric magnetic fields increases ionized metal densities. A larger fraction of sputtered target atoms thereby strike the wafer 16 (with greater directionality).

Within the reactor 10, sputtering typically is performed at a pressure of about 0-2 milliTorr. The power applied to the target 14 may be, for example, about 18 kW and the RF bias signal applied to the pedestal 18 may be about 250 W or less (although other target powers and RF biases may be used).

If reactive sputtering is to be performed, nitrogen is flowed into the chamber 12 from the second gas supply 25 together with argon provided from the working gas supply 23. Nitrogen reacts with the target 14 to form a nitrogen film on the target 14 so that metal nitride is sputtered therefrom. Additionally, non-nitrided atoms are also sputtered from the target 14. These atoms can combine with nitrogen to form metal nitride in flight or on the wafer 16.

FIG. 1B is a schematic cross-sectional view of a second conventional PVD reactor 10′. The reactor 10′ of FIG. 1B may have all of the components described above in connection with the reactor 10 of FIG. 1A. In addition the reactor 10′ includes a coil 38 which is disposed within the chamber 12 and surrounds a portion of the interior volume of the chamber 12. The coil 38 may comprise a plurality of coils, a single turn coil, a single turn material strip, or any other similar configuration. The coil 38 is positioned along the inner surface of the chamber 12, between the target 14 and the pedestal 18.

An RF power source 40 is connected to the coil 38 and is controlled by the controller 30. During sputter-deposition operation of the reactor 10′, the RF power source 40 is operated to energize the coil 38, to enhance the plasma within the chamber 12 (by ionizing target atoms sputtered from the target 14). The coil 38 may be energized at about 2 MHz at a power level of 1-3 kW. Other frequencies and/or powers may be used. As with the reactor 10 of FIG. 1A, metal ion densities can reach about 10¹⁰-10¹¹ metal ions/cm³. However, because of the energy provided by the coil 38, high metal ion densities may be provided over a wider region of the plasma of the reactor 10 than for the plasma of the reactor 10 of FIG. 1A. The chamber pressures employed in the reactor 10′ of FIG. 1B may be similar to those described above in connection with the reactor 10 of FIG. 1A. As was the case with the reactor 10 of FIG. 1A, stationary ring magnets may be used in the reactor 10′ of FIG. 1B in place of the rotating magnetron 36.

FIG. 1C is a schematic cross-sectional view of a third conventional PVD reactor 10″. The reactor 10″ of FIG. 1C may have all the components of the reactor 10′ of FIG. 1B, except that in place of the asymmetric magnetron 36 shown in FIG. 1B, a balanced magnetron 42 (FIG. 1C) may be provided. The magnetic field provided by the balanced magnetron 42 does not extend as far into the chamber 12 as the magnetic field provided by the asymmetric magnetron 36. The reactor 10″ of FIG. 1C is therefore operated at a higher pressure (e.g., 10-100 milliTorr) so that metal atoms sputtered from the target 14 thermalize and have a greater opportunity for ionization. That is, at the higher pressure at which the reactor 10″ operates, metal atoms sputtered from the target 14 experience more collisions (have a smaller mean free path between collisions) and due to increased collisions have more random motion or a longer transit time within the plasma of the reactor 10″ and thus more opportunity to ionize. Metal ion densities within the reactor 10″ may reach about 10¹⁰-10¹¹ metal ions/cm³, but over a larger volume than in the reactor 10 of FIG. 1A.

As in the case of the reactors 10, 10′, stationary ring magnets may be employed in the reactor 10″ of FIG. 1C.

FIG. 1D is a schematic cross-sectional view of a fourth conventional PVD reactor 10′″. The reactor 10′″ includes a specially shaped target 242 and a magnetron 280. The target 242 or at least its interior surface is composed of the material to be sputter deposited (e.g., copper or other materials). Reactive sputtering of materials like TiN and TaN can be accomplished by using a Ti or Ta target and including gaseous nitrogen in the plasma. In such a case, the nitrogen is introduced into the reactor 10′″ from a nitrogen gas source which is not shown in FIG. 1D. Other combinations of metal targets and reactive gases may be employed.

The target 242 includes an annularly shaped downwardly facing vault 118 facing a wafer 120 which is to be sputter coated. The vault could alternatively be characterized as an annular roof. The vault 118 has an aspect ratio of its depth to radial width of at least 1:2 and preferably at least 1:1. The vault 118 has an outer sidewall 122 outside of the periphery of the wafer 120, an inner sidewall 124 overlying the wafer 120, and a generally flat vault top wall or roof 244 (which closes the bottom of the downwardly facing vault 118). The target 242 includes a central portion forming a post 126 including the inner sidewall 124 and a generally planar face 128 in parallel opposition to the wafer 120. A cylindrical central well 136 of the target 242 is formed between opposed portions of the inner target sidewall 124. The target 242 also includes a flange 129 that is vacuum sealed to a grounded chamber body 150 of the reactor 10′″ through a dielectric target isolator 152.

The wafer 120 is clamped to a heater pedestal electrode 154 by, for example, a clamp ring 156 although electrostatic chucking may alternatively be employed. An electrically grounded shield 158 acts as an anode with respect to the cathode target 242, which is negatively energized by a power supply 160. As an alternative to DC sputtering, RF sputtering can also be employed, and may be particularly useful for sputtering non-metallic targets.

An electrically floating shield 162 is supported on the electrically grounded shield 158 or chamber 150 by a dielectric shield isolator 164. A cylindrical knob 166 extending downwardly from the outer target sidewall 122 and positioned inwardly of the uppermost part of the floating shield 162 protects the upper portion of the floating shield 162 and the target isolator 152 from sputter deposition from the strong plasma disposed within the target vault 118. The gap between the upper portion of the floating shield 162 and the target knob 166 and the flange 129 is small enough to act as a dark space (preventing a plasma from propagating into the gap).

A working gas such as argon is supplied into the reactor 10′″ from a gas source 168 through a mass flow controller 170. A vacuum pumping system 172 maintains the chamber at a reduced pressure, typically a base pressure of about 10⁻⁸ Torr. An RF power supply 174 RF biases the pedestal electrode 154 through an isolation capacitor (not shown), to produce a negative DC self-bias. Alternatively, the RF power supply may be omitted and the pedestal electrode 154 may be allowed to float to develop a negative self-bias. A controller 176 regulates the power supplies 160, 174, mass flow controller 170, and vacuum system 172 (e.g., according to a sputtering recipe stored in the controller 176). The controller 176 also may control the position and/or temperature of the pedestal electrode 154.

The magnetron 280 includes inner and outer top magnets 272, 274 overlying the vault roof 244. Side magnets 282, 284 disposed outside of the vault sidewalls 122, 124 have opposed vertical magnetic polarities but are largely decoupled from the top magnets 272, 274 because they are supported on a magnetic yoke 188 by non-magnetic supports 286, 288. As a result, the side magnets 282, 284 create a magnetic field B in the vault 118 that has two generally anti-parallel components extending radially across the vault 118 as well as two components extending generally parallel to the trough sidewalls. Thus the magnetic field B extends over a substantial depth of the vault 118 and repels electrons from the sidewalls 122, 124. A magnetic field B′ is formed by top magnets 272, 274.

A motor 190 is supported on the chamber body 150 by means of a cylindrical sidewall 192 and a roof 194, which are preferably electrically isolated from the biased target flange 129. The motor 190 has a motor shaft connected to the yoke 188 at a central axis 116 of the target 242. The motor 190 may rotate the magnetron 280 about the axis 116 at a suitable rate (e.g., a few hundred rpm). The yoke 188 is asymmetric and may be shaped as a sector. Mechanical counterbalancing may be provided to reduce vibration in the rotation of the axially offset magnetron 280.

Some or all of the magnets of the magnetron 280 may be replaced by stationary ring magnets.

The pressure level employed during sputtering in the reactor 10′″ of FIG. 1D may be similar to the pressure level employed during sputtering in the reactor 10 of FIG. 1A. The reactor 10′″ of FIG. 1D produces ionized metal densities in the range of 10¹⁰-10¹¹ metal ions/cm³ without requiring a coil and over a larger volume than in the reactor 10 of FIG. 1A. Target power may be in the range of about 20-40 kW although other power ranges may be employed.

A reactor of the type shown in FIG. 1D is disclosed in U.S. Pat. No. 6,277,249. That patent is incorporated herein by reference in its entirety. U.S. Pat. No. 6,251,242 is related to U.S. Pat. No. 6,277,249 and is also incorporated herein by reference in its entirety.

The multi-layer structure of typical semiconductor devices requires that connections be made between layers of the devices. For this purpose, holes are formed through dielectric layers that isolate adjacent conductive layers from each other, and the holes are filled with conductive metal. If the lower layer to which the connection is made is the semiconductor substrate, then the hole is referred to as a “contact”; if the lower layer is a metallization layer then the hole is referred to as a “via”. Henceforth, and in the appended claims, the term “via” should be understood to include both contact holes and via holes, as well as other similar features such as lines and/or trenches (e.g., as in a single damascene context, lines and/or trenches may employ their own barrier layers (described below) as is known in the art). As used in the appended claims, the term “via” also encompasses single damascene and dual damascene structures, both of which are familiar to those who are skilled in the art.

With the advent of the use of copper for the metallization layers in semiconductor devices, it has become conventional to coat vias with a barrier layer before filling with copper. The purpose of the barrier layer is to prevent diffusion of the copper into the dielectric layer through which the via is formed.

FIG. 2 is a schematic cross-sectional view of a via in which a barrier layer has been formed, and before filling with copper. In FIG. 2 reference numeral 400 indicates the via and reference numeral 420 indicates the barrier layer. The via 400 has sidewalls 410 and a bottom wall 430. Reference numeral 440 indicates a dielectric layer through which the via is formed. Reference numeral 460 indicates the underlying layer, in which a conductive feature 480 is formed. Electrical contact is to be made to the conductive feature 480 by means of the via 400.

It should be noted that FIG. 2 is not necessarily drawn to scale. For example, the aspect ratio (ratio of height to width) of the via 400 is shown as being approximately two; in practice, vias may have aspect ratios that are considerably greater than two. Furthermore, the thickness of the conductive feature 480 may be much greater than the thickness of the barrier layer 420. For purposes of illustration, it may be considered that the thickness of the barrier layer 420 is substantially exaggerated in the drawing.

A problem that is encountered in connection with barrier layers is that the presence of the barrier layer 420 at the via bottom wall 430 tends to increase the contact resistance in the conductive path to the conductive feature 480. Thus, it is desirable that the barrier layer at the via bottom wall 430 be as thin as possible—ideally, non-existent. However, it is in general difficult to make the barrier layer 420 at the via bottom wall 430 thin while still providing satisfactory coverage on the sidewalls 410 of the via 400. Accordingly, conventional practices may require that trade-offs be made between the competing goals of thin or non-existent bottom coverage by a barrier layer and thorough sidewall coverage by the barrier layer.

It would accordingly be desirable to provide a process for sputter-depositing a barrier layer which provides both good sidewall coverage and low bottom coverage.

### SUMMARY OF THE INVENTION

According to a first aspect of the invention a method of operating a sputtering chamber is provided. The inventive method includes using the chamber to sputter-deposit a layer of material in a via formed on a substrate, wherein the via has a bottom wall, and the sputter-deposition is performed while applying a power signal at a first level to a sputtering target that is part of the chamber. The inventive method further includes using the chamber to back-sputter at least a portion of the material layer from the bottom wall of the via, wherein the back-sputtering is performed while applying a power signal at a second level to the sputtering target, with the second level being higher than the first level.

According to a second aspect of the invention, a method of operating a sputtering chamber includes using the chamber to sputter-deposit, during a first process step, a layer of material in a via formed on a substrate, with the via having a bottom wall. The inventive method according to the second aspect of the invention further includes using the chamber to back-sputter, during a second process step subsequent to the first process step, at least a portion of the material layer from the bottom wall of the via. The back-sputtering is performed while applying a power signal at a level of at least 6 kW to a sputtering target that is part of the chamber.

According to further aspects of the invention, the above methods are implemented in a plasma sputtering reactor that includes a sealable chamber; a pedestal adapted to support a substrate within the chamber; a sputtering target in opposition to the pedestal and adapted to be electrically coupled for plasma sputtering; and a controller adapted to control the reactor such that the reactor performs the above-described method steps. If a metal nitride is to be deposited, then nitrogen is introduced into the chamber and reactive sputtering is performed.

In the above-described inventive processes the back-sputtering may thin or partially or completely eliminate a barrier layer on the bottom wall of a via, thereby lowering contact resistance. The material back-sputtered from the bottom wall of the via may, to a large extent, be deposited on the sidewalls of the via, thereby improving the protective function of the barrier layer relative to the dielectric layer in which the via is formed. Energizing the target with a substantial power signal during back-sputtering and/or with a higher level power signal than during an initial sputter-deposition step, has been found to enhance the efficiency of the back-sputtering step.

Other features and aspects of the present invention will become more fully apparent from the following detailed description, the appended claims and the accompanying drawings.

### BRIEF DESCRIPTION OF THE DRAWINGS

FIG. 1A is a schematic cross-sectional view of a first conventional plasma sputtering reactor;

FIG. 1B is a schematic cross-sectional view of a second conventional plasma sputtering reactor;

FIG. 1C is a schematic cross-sectional view of a third conventional plasma sputtering reactor;

FIG. 1D is a schematic cross-sectional view of a fourth conventional plasma sputtering reactor;

FIG. 2 is a schematic cross-sectional view of a conventional via formed in a dielectric layer on a semiconductor substrate;

FIG. 3 is a graph that illustrates back-sputter efficiency results obtained from a number of different processing regimes;

FIG. 4 is a graph that illustrates deposition rate results obtained from a number of different processing regimes;

FIG. 5 is a graph that illustrates non-uniformity results obtained from a number of different processing regimes;

FIG. 6 is a flow chart that illustrates a sputtering process performed in accordance with the present invention;

FIG. 7 is a cross-sectional view, similar to FIG. 2, showing an effect of a back-sputtering step of the inventive process of FIG. 6;

FIG. 8A is a micrograph showing vias that have been coated with a barrier layer by the inventive process of FIG. 6;

FIG. 8B is an enlarged micrograph showing a detail of a via of FIG. 8A;

FIG. 9A is a micrograph of a dual damascene structure that has been coated with a barrier layer by the inventive process of FIG. 6; and

FIG. 9B is an enlarged micrograph showing a detail of the dual damascene structure of FIG. 9A.

### DETAILED DESCRIPTION

In accordance with the invention, a barrier layer is formed in a via of a substrate in a two-step process. In the first step, sputter-deposition is performed while a relatively low level of power is applied to a sputtering target and no bias signal is supplied to a pedestal on which the substrate is supported. In the second step, a substantial bias signal is applied to the pedestal and the target continues to be substantially energized, possibly at a level higher than the level applied in the first step. During the second step, there is back-sputtering of material deposited on the bottom wall of the via during the first step. This reduces the contact resistance through the via. Also, some of the material back-sputtered from the bottom wall of the via adds to the barrier layer material on the sidewalls of the via, thereby improving sidewall coverage.

It is an advantage of the present invention that the initial sputter-deposition step, and the subsequent back-sputtering step can be balanced by selecting the respective durations of the two steps to provide satisfactory sidewall coverage and minimum bottom wall coverage.

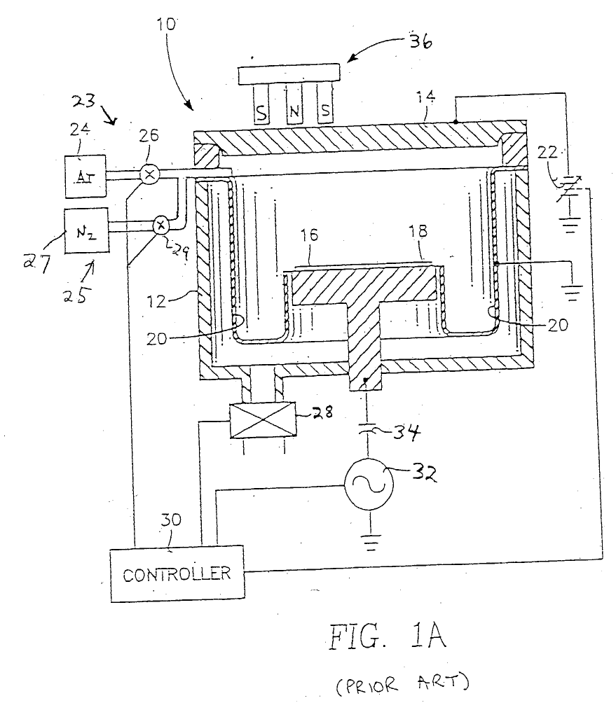

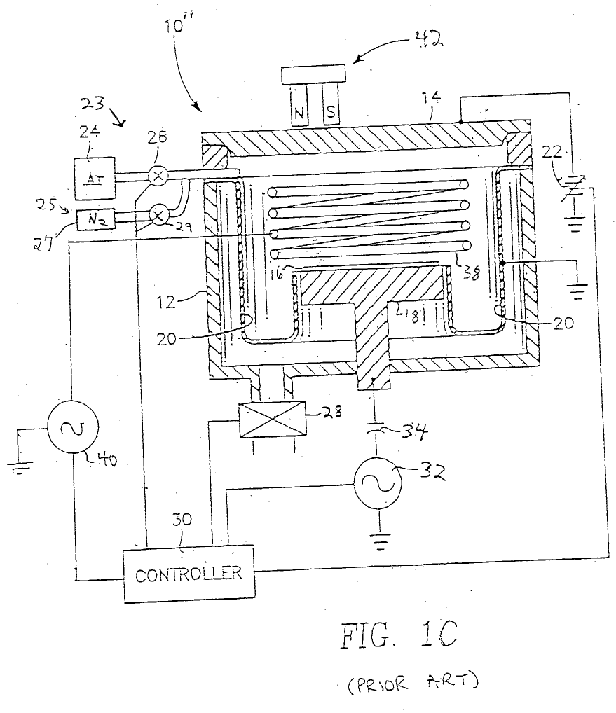

To determine favorable parameters for the two process steps, characteristics of a number of different process regimes were investigated. To determine a favorable combination of pedestal bias and target power, a characteristic that will be referred to as “back-sputter efficiency” was investigated. The back-sputter efficiency for a given level of pedestal bias is defined as the deposition rate with zero pedestal bias divided by the deposition rate at the given pedestal bias level. FIG. 3 is a graph that illustrates back-sputter efficiency results obtained for various combinations of target power and pedestal bias. The results shown in FIG. 3 were obtained using a reactor like that shown in FIG. 1A, with a tantalum target for tantalum deposition, and are based on measurements made with respect to blanket oxide substrates to which sputter-deposition processes were applied at a pressure of 1 mT. The underlying deposition rate measurements for the back-sputter efficiency calculations were obtained by measuring sheet resistance (Rs) for the deposited layers of material. Pedestal biasing was performed at 13.56 MHz, although other frequencies may be employed.

In FIG. 3, curve 300 indicates back-sputter efficiency results obtained at a target power of 12 kW; curve 302 indicates back-sputter efficiency results obtained at a target power of 16 kW; curve 304 indicates back-sputter efficiency results obtained at a target power of 8 kW; curve 306 indicates back-sputter efficiency results obtained at a target power of 20 kW; and curve 308 indicates back-sputter efficiency results obtained at a target power of 4 kW. It will be noted that back-sputter efficiency generally increased with increasing pedestal bias, and that the highest back-sputter efficiency was observed for the combination of 12 kW target power and 1,000 W pedestal bias. It is desirable to operate with high back-sputter efficiency during a second (back-sputtering) step of the inventive process.

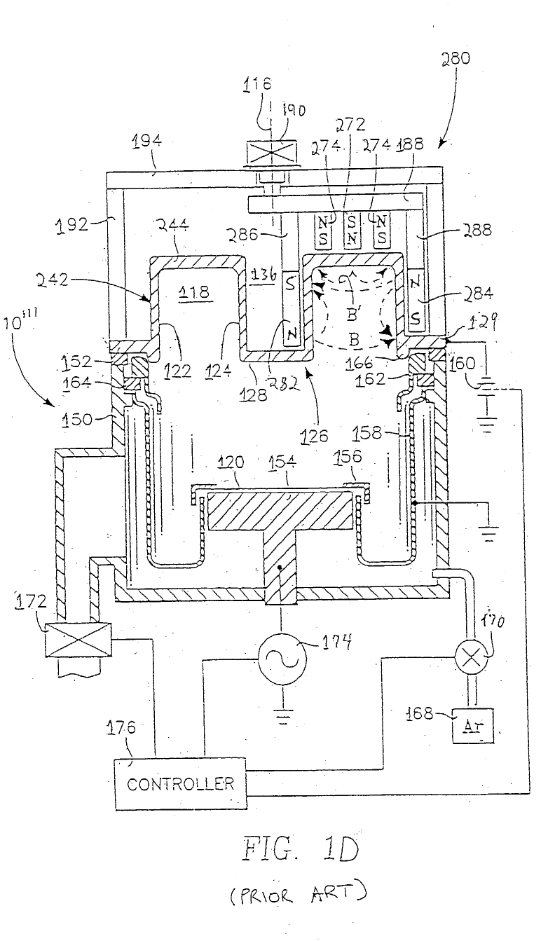

FIG. 4 is a graph that illustrates deposition rate results obtained for various process regimes. The results presented in FIG. 4 were obtained under the same conditions as for the results presented in FIG. 3. In FIG. 4, curve 310 indicates deposition rate results obtained at a target power of 20 kW; curve 312 indicates deposition rate results obtained at a target power of 16 kW; curve 314 indicates deposition rate results obtained at a target power of 12 kW; curve 316 indicates deposition rate results obtained at a target power of 8 kW; and curve 318 indicates deposition rate results obtained at a target power of 4 kW. To minimize the amount of material deposited on the bottom wall 430 of the via 400 during an initial sputter-deposition step, it is desirable to operate with low target power (low ionization) and at zero pedestal bias. Operating at low target power entails trade-offs in terms of deposition time and uniformity (as described below).

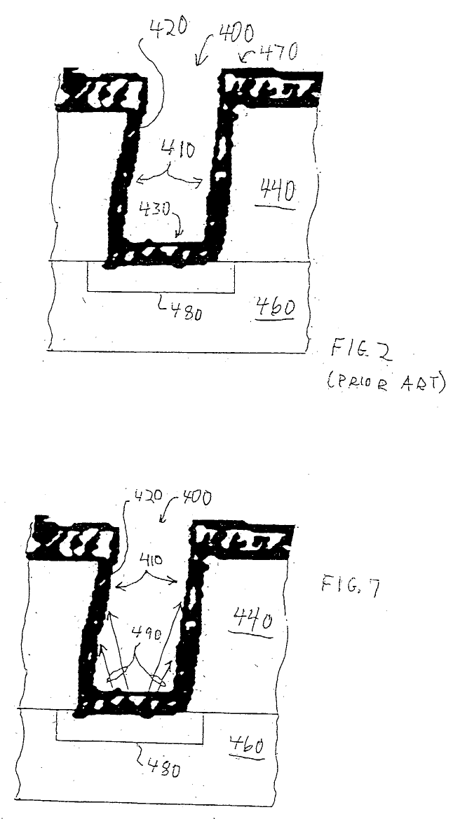

FIG. 5 is a graph that indicates non-uniformity results obtained for a variety of process regimes. The non-uniformity results presented in FIG. 5 were obtained from sheet resistance measurements and were obtained under the same conditions as the results of FIGS. 3 and 4 following sputter deposition, but prior to back sputtering. In FIG. 5, curve 320 indicates non-uniformity results obtained at a target power of 12 kW; curve 322 indicates non-uniformity results obtained at a target power of 8 kW; curve 324 indicates non-uniformity results obtained at a target power of 16 kW; curve 326 indicates non-uniformity results obtained at a target power of 20 kW; and curve 328 indicates non-uniformity results obtained at a target power of 4 kW. The non-uniformity results obtained at 1,000 W pedestal bias may be center-thin; the non-uniformity results obtained at zero pedestal bias may be center-thick.

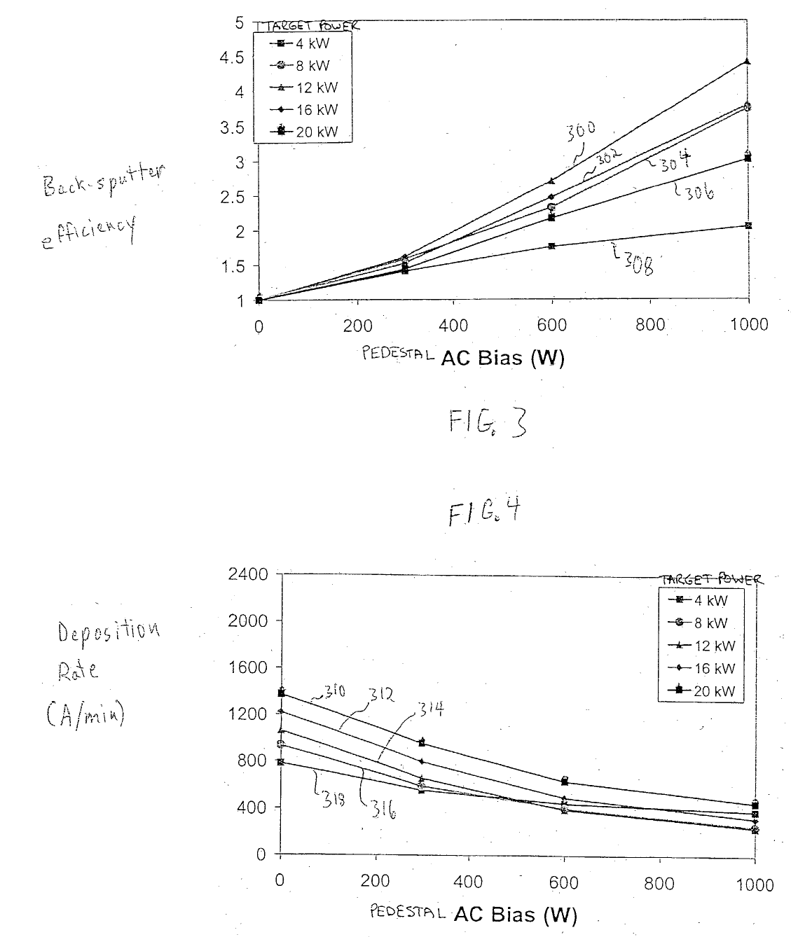

FIG. 6 is a flow chart that illustrates a process performed in accordance with the present invention. The process of FIG. 6 may be performed, for example, in a sputtering reactor of the type illustrated in FIG. 1A.

The process of FIG. 6 begins with a step 330, at which a sputter deposition process is performed. That is, referring to FIG. 1A, the target 14 is energized by means of the DC power supply 22 and at the same time argon is flowed via the mass flow controller 26 to the chamber 12. The power signal supplied to the target 14 by the DC power supply 22 may be at a lower level than is customarily employed in sputter deposition processes. For example, the power signal supplied to the target 14 by the DC power supply 22 may be in the range 2-10 kW. There may be no bias signal supplied to the pedestal 18 by the RF power supply 32. A bias signal of up to 300 W may be supplied, but any bias signal greater than zero would tend to increase bottom coverage and would not be advantageous.

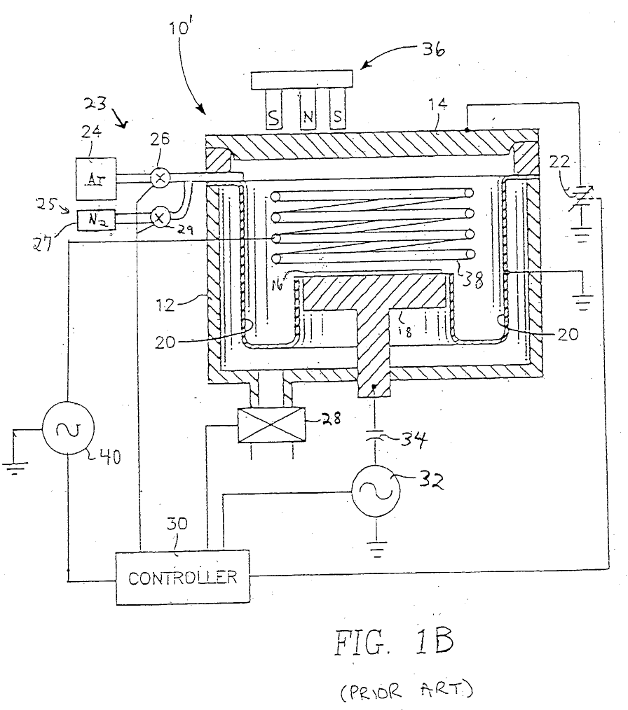

The energized target 14 ignites the argon to form a plasma so that material is sputtered from the target 14 and deposited on the substrate 16. One or more vias 400 on the substrate 16 are coated in the manner illustrated in FIG. 2. The sputter deposition step 330 is performed for a length of time sufficient to coat a corner 470 of the via 400 so that an appropriate amount of the layer 420 is left on the corner 470 after subsequent back-sputtering.

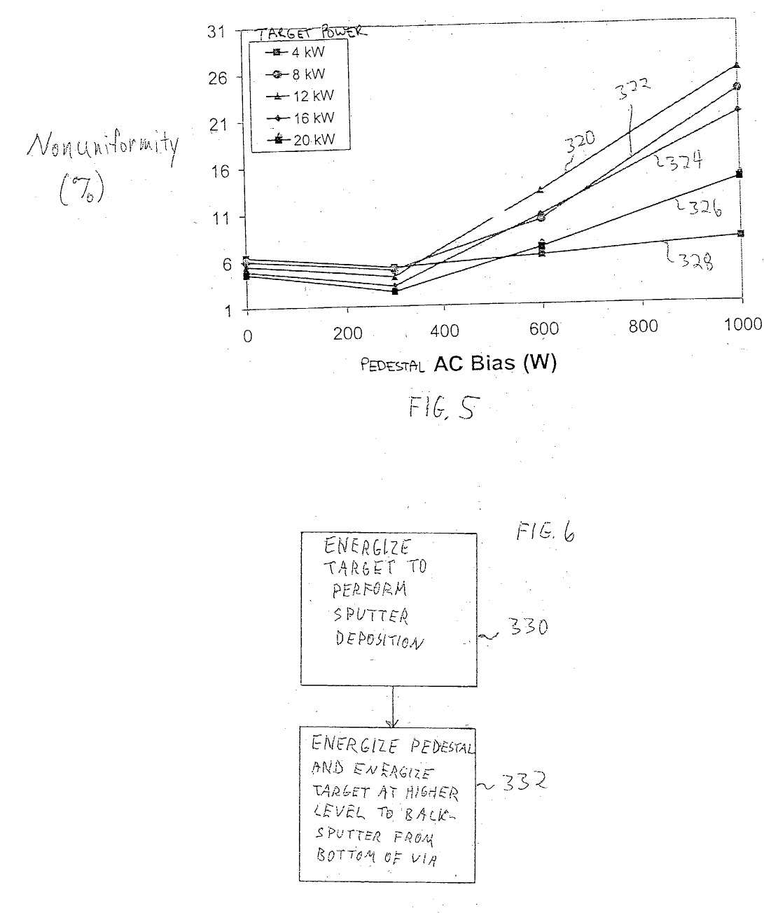

Following the initial step 330 is a subsequent step 332 at which the pedestal 18 is energized with a bias signal from the RF power supply 32 at a level that may be in the range 600-1,000 W. Also in the subsequent step 332, the target 14 is energized with a power signal that may be at a higher level than the power signal employed in step 330, and may be in the range 6-20 kW. During the second step 332, back-sputtering occurs with respect to the layer 420 at the bottom wall 430 of the via 400. In FIG. 7, arrows 490 indicate back-sputtering of material from the bottom wall 430 of the via 400 to the side walls 410.

In one embodiment of the invention, the first step was performed at 8 kW target power and zero pedestal bias for ten seconds, and the second step was performed at 12 kW target power and 1,000 W pedestal bias for thirty seconds. In both steps, the chamber pressure was 1 mT. Other target powers, pedestal biases, step durations and chamber pressures may be employed.

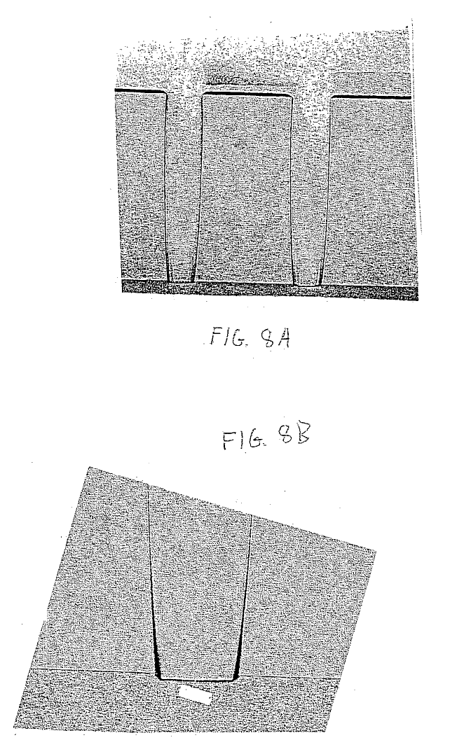

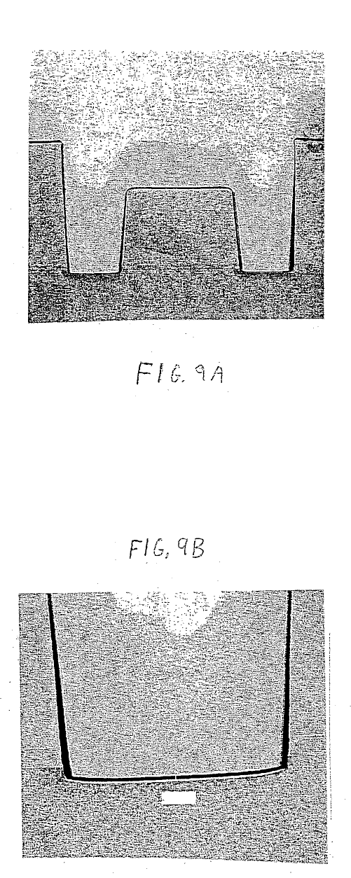

FIG. 8A is a micrograph of vias coated with a barrier layer in accordance with the inventive process and using the process parameters set forth in the preceding paragraph. FIG. 8B is an enlarged micrograph showing a detail at the bottom of one of the vias shown in FIG. 8A. FIG. 9A is a micrograph showing a dual damascene structure coated with a barrier layer by the inventive process performed with the parameters set forth in the preceding paragraph. FIG. 9B is an enlarged micrograph showing details of the bottom of the dual damascene structure of FIG. 9A.

In both of the barrier layers shown in FIGS. 8A-9B, good sidewall coverage was obtained with relatively low bottom wall coverage: in the vias of FIG. 8A the bottom coverage was approximately 12.5% and in the dual damascene structure of FIG. 9A the bottom coverage was approximately 35.2%. Bottom coverage refers to the ratio of the thickness of a barrier layer on a via bottom (bottom wall 430 in FIGS. 2 and 7) to the thickness of the barrier layer on top of the field oxide (dielectric layer 440 in FIGS. 2 and 7).

The present invention has been described as applied in a plasma sputtering reactor of the type illustrated in FIG. 1A. It is also contemplated to apply the present invention in other types of plasma sputtering reactors, including those illustrated in FIGS. 1B-1D. When a coil is present in the chamber (e.g., the coil 38 of FIG. 1B or 1C) the coil power is an additional variable that is available to adjust in one or both of the two steps of the inventive process to obtain favorable sidewall coverage with minimal bottom coverage.

The foregoing description discloses only exemplary embodiments of the invention; modifications of the above-disclosed apparatus and methods which fall within the scope of the invention will be readily apparent to those of ordinary skill in the art. For example, an embodiment of the invention has been described in which the same chamber pressure was maintained for both steps of the inventive two-step process. However, it is contemplated to change the chamber pressure from the first step to the second step.

Chamber pressures in the range 1-5 mT may, for example, be used in the first step of the inventive two-step process, whereas any practical chamber pressure up to 2 mT may, for example, be used in the second step of the inventive two-step process.

It is contemplated to employ the inventive two-step process to deposit barrier layers of Ta, TaN, and other metals and nitrides. It is further contemplated to employ the inventive two-step process in depositing metal layers other than barrier layers.

Instead of applying an RF bias signal to the pedestal, a DC bias signal may be applied. Other process parameters than those described herein may be employed. One or more of the steps of the process of FIG. 6 may be implemented in suitable computer program code as one or more computer program products. Each inventive computer program product may be carried by a medium readable by a computer (e.g., a carrier wave signal, a floppy disk, a hard drive, a random access memory, etc.). Such computer program code and/or computer program products may be executed, for example, by one or more of the controllers 30, 176 of FIGS. 1A-1D.

It may be desirable to control (via the controllers 30, 176 of FIGS. 1A-1D) the temperature of a substrate during back-sputter (e.g., to prevent excessive heating during a long back-sputter step). This may be achieved, for example, via control of a resistive heating element (not shown) and/or a liquid cooling system (not shown) associated with the pedestal 18, 154.

In at least one embodiment of the invention, a four step process is provided for forming a barrier in a via. The via is defined in a dielectric layer over a copper feature (e.g., similar to FIG. 7), and may be part of a single or a dual damascene structure.

The four step process includes the steps of:

(A) sputter depositing a first barrier layer onto the sidewalls and bottom of the via by performing a first sputter deposition process for a first time period at (1) a first target power; and (2) a first pedestal bias;

(B) back sputtering the first barrier layer on the bottom of the via to expose at least a portion of the copper feature by performing a first back sputter process for a second time period at (1) a second target power that is greater than the first target power; and (2) a second pedestal bias that is greater than the first pedestal bias;

(C) sputter depositing a second barrier layer onto the sidewalls and bottom of the via by performing a second sputter deposition process for a third time period at (1) a third target power; and (2) a third pedestal bias; and

(D) back sputtering the second barrier layer on the bottom of the via to at least reduce a thickness of the second barrier layer over the copper feature by performing a second back sputter process for a fourth time period at (1) a fourth target power that is greater than the third target power; and (3) a fourth pedestal bias that is greater than the third pedestal bias.

In one particular embodiment, the first barrier layer may comprise tantalum nitride and the second barrier layer may comprise tantalum. Other suitable barrier layers also may be employed (e.g., titanium, titanium nitride, tungsten, tungsten nitride, etc.). The four step process may be performed in a single sputtering chamber (e.g., such as one of the chambers of FIGS. 1A-1D); or one or more of the steps may be performed in a separate chamber.

TABLE 1 illustrates exemplary process parameters for the above-described four step process when a Ta/TaN barrier is formed therewith in the chamber of FIG. 1A. Numbers in ( ) represent preferred values. It will be understood that these parameters are merely representative, and that other operating parameters may be employed. Deposition time depends on thickness of the Ta and TaN layers, as does back sputter time. In general, back sputtering requires more time than deposition.

TABLE 1

| | CHAMBER | TARGET | PEDESTAL BIAS | |
|---|---|---|---|---|
| | PRESSURE | POWER | (Watts at 13.56 | |
| PROCESS STEP | (milliTorr) | (kWatts) | MHz) | |
| TaN DEPOSITION | 1-5 (1) | 2-10 (8) | 0-300 | (0) |
| TaN BACK SPUTTER | 1-2 (1) | 6-20 (12) | 600-1000 | (1000) |
| Ta DEPOSITION | 1-5 (1) | 2-10 (8) | 0-300 | (0) |
| Ta BACK SPUTTER | 1-2 (1) | 6-20 (12) | 600-1000 | (1000) |

Note, if an RF coil is employed (e.g., such as in the chambers of FIGS. 1B and 1C), the RF coil may be back sputtered during each back sputter step to improve via sidewall coverage and/or may be employed to increase ionization of argon or target atoms to increase back sputtering.

Accordingly, while the present invention has been disclosed in connection with exemplary embodiments thereof, it should be understood that other embodiments may fall within the spirit and scope of the invention, as defined by the following claims.

The invention claimed is:

1. A method of operating a sputtering chamber, comprising:
using the chamber to sputter-deposit a layer of material in a via formed on a substrate, the via having a bottom wall, the sputter-deposition being performed while applying a power signal at a first level to a sputtering target of the chamber; and
using the chamber to back-sputter at least a portion of the material layer from the bottom wall of the via, the back-sputtering being performed while applying a power signal at a second level to the sputtering target, the second level being higher than the first level.

2. The method of claim 1, wherein a pressure level in the chamber during the back-sputtering is the same as a pressure level in the chamber during the sputter-deposition.

3. The method of claim 1, wherein during the sputter-deposition no bias signal is applied to a pedestal on which the substrate is supported.

4. The method of claim 3, wherein during the back-sputtering a bias signal in the range of 600-1,000 W is applied to the pedestal on which the substrate is supported.

5. The method of claim 1, wherein during the back-sputtering a bias signal in the range of 600-1,000 W is applied to a pedestal on which the substrate is supported.

6. The method of claim 5, wherein during the back-sputtering a bias signal of substantially 1,000 W is applied to the pedestal on which the substrate is supported.

7. The method of claim 1, wherein the power signal at the first level is in the range of 2-10 kW and the power signal at the second level is in the range of 6-20 kW.

8. The method of claim 7, wherein the power signal at the first level is substantially 8 kW and the power signal at the second level is substantially 12 kW.

9. The method of claim 8, wherein no bias signal is applied during the sputter-deposition to a pedestal on which the substrate is supported, and during the back-sputtering a bias signal of substantially 1,000 W is applied to the pedestal.

10. The method of claim 1, wherein the material layer is a barrier layer.

11. The method of claim 10, wherein the sputter deposition includes reactive sputtering such that the barrier layer is a metal nitride.

12. The method of claim 11, wherein the metal nitride is TaN.

13. A method of operating a sputtering chamber, comprising:
using the chamber to sputter-deposit, during a first process step, a layer of material in a via formed on a substrate, the via having a bottom wall; and
using the chamber to back-sputter, during a second process step subsequent to the first process step, at least a portion of the material layer from the bottom wall of the via, the second process step being performed while applying a power signal at a level of at least 6 kW to a sputtering target of the chamber.

14. The method of claim 13, wherein the power signal applied to the sputtering target during the second process step is in the range of 6-20 kW.

15. The method of claim 14, wherein the power signal applied to the sputtering target during the second process-step is substantially 12 kW.

16. The method of claim 13, wherein a pressure level in the chamber during the second process step is the same as a pressure level in the chamber during the first process step.

17. The method of claim 13, wherein during the first process step no bias signal is applied to a pedestal on which the substrate is supported.

18. The method of claim 17, wherein during the second process step a bias signal in the range of 600-1,000 W is applied to the pedestal on which the substrate is supported.

19. The method of claim 13, wherein during the first process step a bias signal of no more than 300 W is applied to a pedestal on which the substrate is supported.

20. The method of claim 19, wherein during the second process step a bias signal in the range of 600-1,000 W is applied to the pedestal on which the substrate is supported.

21. The method of claim 13, wherein during the second process step a bias signal in the range of 600-1,000 W is applied to a pedestal on which the substrate is supported.

22. The method of claim 21, wherein during the second process step a bias signal of substantially 1,000 W is applied to the pedestal.

23. The method of claim 13, wherein the material layer is a barrier layer.

24. The method of claim 23, wherein the first process step includes reactive sputtering such that the barrier layer is a metal nitride.

25. The method of claim 24, wherein the metal nitride is TaN.

26. A plasma sputtering reactor, comprising:
a sealable chamber;
a pedestal adapted to support a substrate within the chamber;
a sputtering target in opposition to the pedestal and adapted to be electrically coupled for plasma sputtering; and
a controller adapted to control the reactor to:
sputter-deposit material from the target to form a layer of the material in a via formed on the substrate, the via having a bottom wall, the sputter deposition being performed while a power signal is supplied to the target at a first level; and
back-sputter at least a portion of the layer from the bottom wall of the via, the back-sputtering being performed while the power signal is supplied to the target at a second level that is higher than the first level.

27. A plasma sputtering reactor, comprising:
a sealable chamber;
a pedestal adapted to support a substrate within the chamber;
a sputtering target in opposition to the pedestal and adapted to be electrically coupled for plasma sputtering; and
a controller adapted to control the reactor to:
sputter-deposit material from the target during a first process step to form a layer of the material in a via formed on the substrate, the via having a bottom wall; and
back-sputter at least a portion of the layer from the bottom wall of the via during a second process step subsequent to the first process step, the second process step being performed while a power signal is supplied to the target at a level of at least 6 kW.

28. The plasma sputtering reactor of claim 27, wherein the controller is further adapted to control the reactor to supply a bias signal to the pedestal in the range of 600-1,000 W during the second process step.

29. The plasma sputtering reactor of claim 28, wherein the controller is further adapted to control the reactor to supply no bias signal to the pedestal during the first process step.

30. The plasma sputtering reactor of claim 28, wherein the controller is further adapted to control the reactor to supply a bias signal of no more than 300 W to the pedestal during the first process step.

31. A plasma sputtering reactor, comprising:
a sealable chamber;
a pedestal adapted to support a substrate within the chamber;
a sputtering target formed of a metal and in opposition to the pedestal and adapted to be electrically coupled for plasma sputtering; and
a controller adapted to control the reactor to:
sputter deposit a layer of a nitride of the metal in a via formed on the substrate, the via having a bottom wall, the sputter deposition being performed while a power signal is supplied to the target at a first level; and
back-sputter at least a portion of the layer from the bottom wall of the via, the back-sputtering being performed while the power signal is supplied to the target at a second level that is higher than the first level.

32. A plasma sputtering reactor, comprising:
a sealable chamber;
a pedestal adapted to support a substrate within the chamber;
a sputtering target formed of a metal and in opposition to the pedestal and adapted to be electrically coupled for plasma sputtering; and
a controller adapted to control the reactor to:
sputter deposit, during a first process step, a layer of a nitride of the metal in a via formed on the substrate, the via having a bottom wall; and
back-sputter at least a portion of the layer from the bottom wall of the via during a second process step subsequent to the first process step, the second process step being performed while a power signal is supplied to the target at a level of at least 6 kW.

33. The plasma sputtering reactor of claim 32, wherein the controller is further adapted to control the reactor to supply a bias signal to the pedestal in the range of 600-1,000 W during the second process step.

34. The plasma sputtering reactor of claim 31, wherein the controller is further adapted to control the reactor to supply no bias signal to the pedestal during the first process step.

35. The plasma sputtering reactor of claim 31, wherein the controller is further adapted to control the reactor to supply a bias signal of no more than 300 W to the pedestal during the first process step.

36. A process for forming a barrier in a via having sidewalls and a bottom defined in a dielectric layer over a copper feature, comprising:
sputter depositing a barrier layer onto the sidewalls and bottom of the via by performing a barrier layer deposition process for a first time period at:
a first target power; and
a first pedestal bias; and
back sputtering the barrier layer on the bottom of the via to at least reduce a thickness of the barrier layer over at least a portion of the copper feature by performing a back sputter process for a second time period at:
a second target power that is greater than the first target power; and
a second pedestal bias that is greater than the first pedestal bias.

37. The process of claim 36 wherein the second time period is greater than the first time period.

38. The process of claim 36 wherein the deposition process and the back sputter process are performed in the same chamber.

39. The process of claim 36 wherein the deposition process and the back sputter process are performed in different chambers.

40. A process for forming a barrier in a via having sidewalls and a bottom defined in a dielectric layer over a copper feature, comprising:
sputter depositing a first barrier layer onto the sidewalls and bottom of the via by performing a first sputter deposition process for a first time period at:
a first target power; and
a first pedestal bias; and
back sputtering the first barrier layer on the bottom of the via to expose at least a portion of the copper feature by performing a first back sputter process for a second time period at:
a second target power that is greater than the first target power; and
a second pedestal bias that is greater than the first pedestal bias.

41. The process of claim 40 further comprising:
sputter depositing a second barrier layer onto the sidewalls and bottom of the via by performing a second sputter deposition process for a third time period at:
a third target power; and
a third pedestal bias; and
back sputtering the second barrier layer on the bottom of the via to at least reduce a thickness of the second barrier layer over at least a portion of the copper feature by performing a second back sputter process for a fourth time period at:
a fourth target power that is greater than the third target power; and
a fourth pedestal bias that is greater than the third pedestal bias.

42. The process of claim 40 wherein the second time period is greater than the first time period.

43. The process of claim 41 wherein the fourth time period is greater than the third time period.

44. The process of claim 41 wherein the first barrier layer comprises tantalum nitride and wherein the second barrier layer comprises tantalum.

45. The process of claim 41 wherein the first sputter deposition process, the first back sputter process, the second sputter deposition process and the second back sputter process are performed in the same sputtering chamber.

46. The process of claim 41 wherein at least one of the first sputter deposition process, the first back sputter process, the second sputter deposition process and the second back sputter process is performed in a different chamber.

47. A process for forming a Ta/TaN barrier in a via having sidewalls and a bottom defined in a dielectric layer over a copper feature, comprising:
sputter depositing a TaN barrier layer onto the sidewalls and bottom of the via by operating a sputtering chamber for a first time period at:
a first target power; and
a first pedestal bias;
back sputtering the TaN barrier layer on the bottom of the via to expose at least a portion of the copper feature by operating the sputtering chamber for a second time period at:
a second target power that is-greater than the first target power; and
a second pedestal bias that is greater than the first pedestal bias;
sputter depositing a Ta barrier layer onto the sidewalls and bottom of the via by operating the sputtering chamber for a third time period at:
a third target power; and
a third pedestal bias; and
back sputtering the Ta barrier layer on the bottom of the via to at least reduce a thickness of the Ta barrier layer over at least a portion of the copper feature by operating the sputtering chamber for a fourth time period at:
a fourth target power that is greater than the third target power; and
a fourth pedestal bias that is greater than the third pedestal bias.
